(19) United States
(12) Patent Application Publication
(10) Pub. No.: US 2024/0275378 A1
(43) Pub. Date: Aug. 15, 2024

(54) HEAD SWITCH FOR A STACKED TRANSISTOR STRUCTURE

(71) Applicant: QUALCOMM INCORPORATED, SAN DIEGO, CA (US)

(72) Inventors: Hayg-Taniel DABAG, San Diego, CA (US); Ibrahim Ramez CHAMAS, Carlsbad, CA (US); Asad Ali NAWAZ, San Diego, CA (US); Waqas AHMAD, San Diego, CA (US)

(21) Appl. No.: 18/494,889

(22) Filed: Oct. 26, 2023

Related U.S. Application Data
(60) Provisional application No. 63/445,599, filed on Feb. 14, 2023.

(51) Int. Cl. H03K 17/56

(52) U.S. Cl. CPC H03K 17/56

(57) ABSTRACT

A head switch architecture for a stacked transistor structure including a first head switch located in an active path, the first head switch configured to provide a supply voltage to a first cascode path, and a second head switch located in an inactive path, the second head switch configured to provide a reduced supply voltage to a second cascode path.

### RELATED APPLICATIONS

This application claims priority to and the benefit of U.S. Provisional Patent Application No. 63/445,599, entitled “HEAD SWITCH FOR A STACKED TRANSISTOR STRUCTURE” filed Feb. 14, 2023, the contents of which are hereby incorporated herein by reference in their entirety as if fully set forth below and for all applicable purposes.

### FIELD

The present disclosure relates generally to electronics, and more specifically to transistors in transceivers.

### BACKGROUND

Wireless communication devices and technologies are becoming ever more prevalent, as are communication devices that operate at 5G NR Sub6 FR1 and millimeter-wave (mmW) FR2 frequencies. Wireless communication devices generally transmit and/or receive communication signals. In a radio frequency (RF) transceiver, a communication signal is typically amplified and transmitted by a transmit section and a received communication signal is amplified and processed by a receive section. A communication device may include multiple transmitters, receivers and antennas and may be capable of communicating on multiple communication bands and frequencies.

In some transceivers, it is desirable to have good linearity and good signal bandwidth, while also minimizing an amount of circuit area. One way of minimizing circuit area is to use what are referred to as thin-film (or thin-oxide) transistors in certain applications. A particular circuit arrangement for these thin-oxide transistors is referred to as a stacked transistor structure. One application for such a stacked transistor structure may be in a mixer and related circuitry. A mixer typically will upconvert a transmit signal and/or downconvert a receive signal.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides a head switch architecture for a stacked transistor structure including a first head switch located in an active path, the first head switch configured to provide a supply voltage to a first cascode path, and a second head switch located in an inactive path, the second head switch configured to provide a reduced supply voltage to a second cascode path.

Another aspect of the disclosure provides a method for biasing a stacked transistor structure including applying a supply voltage to a first cascode path, applying a reduced supply voltage to a second cascode path, and applying a gate voltage to a gate of a cascode transistor in the first cascode path to transition the cascode transistor in the first cascode path from an off and/or a stand-by state to a mission mode state.

Another aspect of the disclosure provides a device including means for applying a supply voltage to a first cascode path, means for applying a reduced supply voltage to a second cascode path, and means for applying a gate voltage to a gate of a cascode transistor in the first cascode path to transition the cascode transistor in the first cascode path from an off and/or a stand-by state to a mission mode state.

Another aspect of the disclosure provides an apparatus including a first head switch circuit coupled between a supply voltage and a first cascode transistor, the first cascode transistor coupled to a plurality of stacked transistors, the first head switch circuit comprising a first path coupled between the supply voltage and the first cascode transistor and configured to provide a first voltage to a first node that is between the first head switch circuit and a terminal of the first cascode transistor, the first head switch circuit further comprising a second path coupled between the supply voltage and the first cascode transistor and configured to provide a second voltage lower than the first voltage to the first node. The apparatus further includes a second head switch circuit coupled between the supply voltage and a second cascode transistor, the second cascode transistor coupled to the plurality of stacked transistors, the second head switch circuit comprising a third path coupled between the supply voltage and the second cascode transistor and configured to provide a third voltage to a second node that is between the second head switch circuit and a terminal of the second cascode transistor, the first head switch circuit further comprising a fourth path coupled between the supply voltage and the second cascode transistor and configured to provide a fourth voltage lower than the third voltage to second node.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2 shows an example of a wireless device having a transmitter and a receiver.

FIG. 3 is a block diagram showing a circuit illustrating a portion of a transceiver of FIG. 2 that may be implemented in a base station or wireless device of FIG. 1.

FIG. 4 is a diagram showing a circuit illustrating a detailed view of a portion of the circuit of FIG. 3.

FIG. 5 is a diagram showing a circuit illustrating an exemplary embodiment of the head switches of FIG. 3 and FIG. 4.

FIG. 6 is a diagram showing a circuit illustrating an exemplary embodiment of the desired voltages associated with the head switches of FIG. 5.

FIG. 7 is a diagram showing a circuit illustrating an exemplary embodiment of an inactive path head switch of FIG. 5 and FIG. 6.

FIG. 8 is a diagram showing a circuit illustrating a detailed view of a portion of the circuit of FIG. 3 and an exemplary embodiment of the circuit of FIG. 5.

FIG. 9 is a diagram showing a circuit in accordance with an exemplary embodiment of the disclosure.

FIG. 10 is a flow chart describing an example of the operation of a method for biasing a stacked transistor structure.

FIG. 11 is a functional block diagram of an apparatus for biasing a stacked transistor structure.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In a stacked transistor structure, a cascode transistor may be connected to a supply voltage, and successive transistors are connected to the cascode transistor with a last transistor connected to a system ground. When thin-oxide transistors are used in such a stacked structure and the supply voltage is relatively high, bias voltage and supply voltage may sometimes cause over voltage conditions in some of the transistors in the stacked transistor structure. Therefore, it is desirable to have a way to precisely control the voltages applied to a stacked transistor structure.

A circuit architecture for a number of different communication circuits, including for example, mixers, amplifiers, etc., uses what is referred to as a stacked transistor structure. As the name implies, a stacked transistor structure couples a drain and source of a number of transistors between a supply voltage and a system ground. In an exemplary embodiment, a stacked transistor structure may have a cascode transistor being connected to a supply voltage and what may be referred to as a tail current transistor being connected to system ground. A number of additional transistors may be connected drain-to-source between the cascode transistor and the tail current transistor.

For example, in a communication mixer, a first (cascode) transistor may have a drain connected to a supply voltage and a source connected to a drain of a second (mixer) transistor. A source of the second (mixer) transistor may be connected to a drain of a third (gain or Gm stage) transistor. A source of the third (Gm) transistor may be connected to a drain of a fourth (tail current source) transistor. A source of the fourth (tail current source) transistor may be connected to a system ground. Other stacked transistor structures may also be used, this being one example.

In this arrangement, the first transistor may be a cascode transistor, the second transistor may be part of a mixer, a third transistor may be part of a gain stage and the fourth transistor may provide degeneration and a tail current to the gain stage.

In order to provide an acceptable trade-off with respect to linearity and bandwidth, in many applications the transistors in the stacked transistor structure are fabricated using thin-film (also called thin-oxide) technology. However, it is difficult to reliably bias a stack of four thin-oxide transistor devices using a relatively high (for example, 1.98V) supply voltage when the transistors are in an on-state, in an off-state and during transitions between off-state and on-state.

As used herein, the term “head switch” refers to a switch that is configured to connect and disconnect a circuit, such as for example a mixer circuit having a stacked transistor structure, to a supply voltage.

In an exemplary embodiment, a head switch for a stacked transistor structure comprises multiple bias paths.

In an exemplary embodiment, the head switch for a stacked transistor structure having multiple bias paths comprises a bias path for cascode transistors in an active path and a bias path for cascode transistors in an inactive path.

In an exemplary embodiment, the bias path for the active path provides supply voltage (in an example, 1.98V) to an active cascode transistor and the bias path for the inactive path provides a regulated voltage (below the exemplary supply voltage of 1.98V) of, for example, 0.8V, to an inactive cascode transistor in the inactive path.

In an exemplary embodiment, a head switch connected to an active path is turned on first, and then the gate voltages of the cascode transistors are transitioned from an “off-state” or “stand-by state” voltage to “mission-mode” or “on-state” voltage.

As used herein, the term “off-state” may refer to a fully off state from which a communication device having the head switch for a stacked transistor structure may be powered on and placed into a stand-by state. As used herein the term “stand-by state” may refer to a state in which the communication device having the head switch for a stacked transistor structure may be powered up, but in which the devices are not fully powered on or processing a communication signal. This stand-by state may also be referred to as a “off” state.” As used herein, the term “mission-mode” or “on-state” may refer to a state where the devices in the head switch for a stacked transistor structure are active and processing a communication signal.

In an exemplary embodiment, turning the active path on first allows a tail current to flow through the stacked transistor structure including a cascode transistor associated with the active path and prevent any tail current from flowing through the cascode transistor in the inactive path. Preventing any tail current from flowing through the cascode transistors in the inactive path allows the inactive path to provide a stable drain voltage (e.g., of approximately 0.8V) to a drain of the cascode transistor in the inactive path. In this manner, off/on and on/off transitions can be accurately accomplished and can be made robust to prevent any excessive or run-away voltage transitions.

In an exemplary embodiment, the head switch for a stacked transistor structure allows high linearity and wide bandwidth operation (e.g., particularly when using thin-oxide transistors) and a relatively high supply voltage, while improving long term reliability.

In an exemplary embodiment, a head switch for a stacked transistor structure allows four thin-oxide transistor devices to be reliably biased using a relatively high (for example, 1.98V) supply voltage when the transistors are in an on-state, in an off-state and during transition between an on-state and an off-state and transitions between an off-state and an on-state.

The voltages described herein are exemplary only and may differ from those shown based on implementation details.

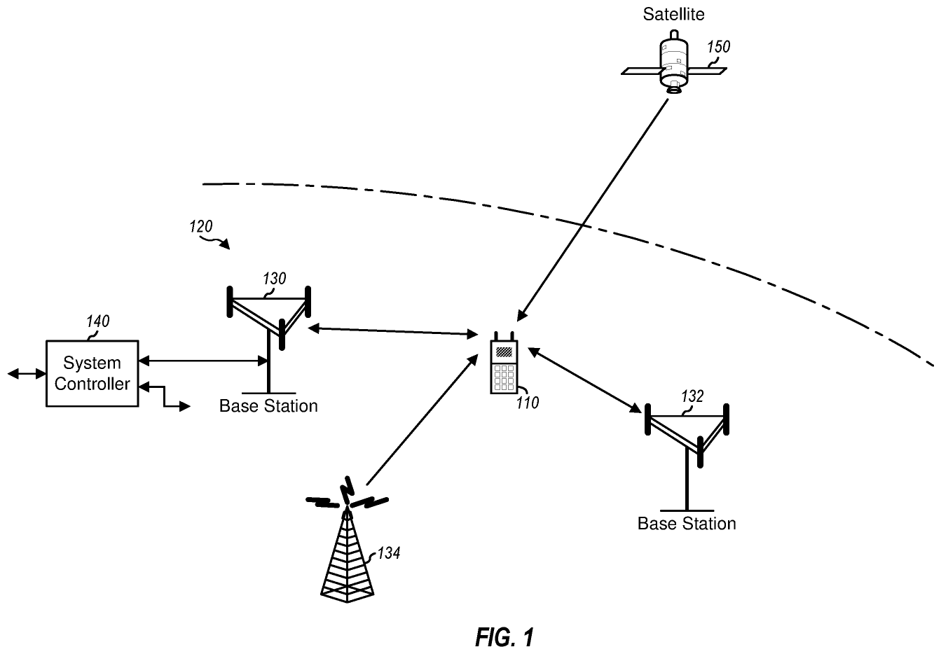

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, an automobile, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134) and/or signals from satellites (e.g., a satellite 150 in one or more global navigation satellite systems (GNSS)), etc.). Wireless device 110 may support one or more radio technologies for wireless communication such as LTE, WCDMA, CDMA 1X, EVDO, TD-SCDMA, GSM, 802.11, 802.15, 5G, Sub6 5G, 6G, UWB, etc.

Wireless device 110 may support carrier aggregation, for example as described in one or more LTE or 5G (also sometimes referred to as new radio (NR) standards. In some embodiments, a single stream of data is transmitted over multiple carriers using carrier aggregation, for example as opposed to separate carriers being used for respective data streams. Wireless device 110 may be able to operate in a variety of communication bands including, for example, those communication bands used by LTE, WiFi, 5G or other communication bands, over a wide range of frequencies. Wireless device 110 may also be capable of communicating directly with other wireless devices without communicating through a network.

In general, carrier aggregation (CA) may be categorized into two types—intra-band CA and inter-band CA. Intra-band CA refers to operation on multiple carriers within the same band. Inter-band CA refers to operation on multiple carriers in different bands.

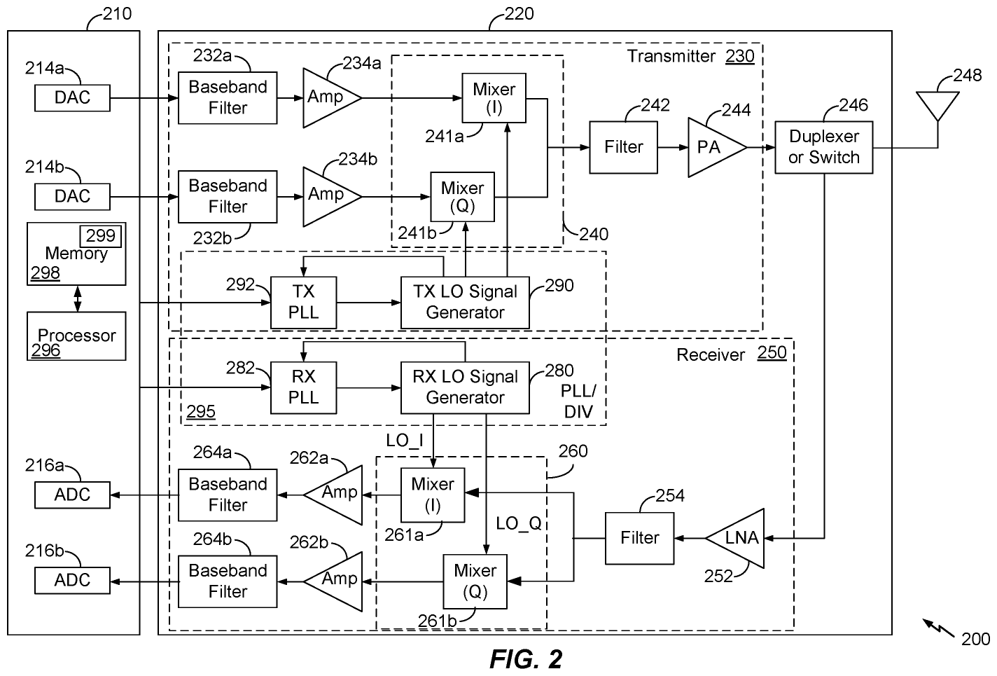

FIG. 2 shows an example of a transceiver 220 having a transmitter 230 and a receiver 250. In general, the conditioning of the signals in the transmitter 230 and the receiver 250 may be performed by one or more stages of amplifier, filter, upconverter, downconverter, etc. These circuit blocks may be arranged differently from the configuration shown in FIG. 2. Furthermore, other circuit blocks not shown in FIG. 2 may also be used to condition the signals in the transmitter 230 and receiver 250. Unless otherwise noted, any signal in FIG. 2, or any other figure in the drawings, may be either single-ended or differential. Some circuit blocks in FIG. 2 may also be omitted.

In the example shown in FIG. 2, wireless device 200 generally comprises the transceiver 220 and a data processor 210. The data processor 210 may include a processor 296 operatively coupled to a memory 298. The memory 298 may be configured to store data and program codes shown generally using reference numeral 299, and may generally comprise analog and/or digital processing components. The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 2, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, lowpass filters 232a and 232b filter the I and Q analog transmit signals, respectively, to remove undesired images caused by the prior digital-to-analog conversion. Amplifiers (Amp) 234a and 234b amplify the signals from lowpass filters 232a and 232b, respectively, and provide I and Q baseband signals. An upconverter 240 having upconversion mixers 241a and 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier (PA) 244 amplifies the signal from filter 242 to obtain the desired output power level and provides a transmit RF signal. The transmit RF signal is routed through a duplexer or switch 246 and transmitted via an antenna 248, or alternatively it can be sent to a separate transmit antenna different from a separate receive antenna. While examples discussed herein utilize I and Q signals, those of skill in the art will understand that components of the transceiver may be configured to utilize polar modulation.

In the receive path, antenna 248 receives communication signals and provides a received RF signal, which can be routed through duplexer or switch 246 and provided to a low noise amplifier (LNA) 252. The duplexer 246 is designed to operate with a specific RX-to-TX duplexer frequency separation, such that RX signals are isolated from TX signals. Alternatively, there may be a separate transmit antenna and separate receive antenna as mentioned above, in which case RX-to-TX isolation can be achieved through the limited coupling between the two antennas. In the case of separate RX and TX antennas, the RX antenna can be coupled directly to LNA 252. The received RF signal is amplified by LNA 252 and filtered by a filter 254 to obtain a desired RF input signal. Downconversion mixers 261a and 261b in a downconverter 260 mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by lowpass filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

In an exemplary embodiment, the RX PLL 282, the TX PLL 292, the RX LO signal generator 280, and the TX LO signal generator 290 may alternatively be combined into a single LO generator circuit 295, which may include common or shared LO signal generator circuitry to provide the TX LO signals and the RX LO signals. Alternatively, separate LO generator circuits may be used to generate the TX LO signals and the RX LO signals.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain components of the transceiver 220 are functionally illustrated in FIG. 2, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules, chips, and/or components. For example, the power amplifier 244, the filter 242, and the duplexer 246 may be implemented in separate modules or as discrete components, while the remaining components illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver stages, one or more power amplifier stages, one or more impedance matching networks, and can be configured to provide good linearity, efficiency, or a combination of good linearity and efficiency.

In an exemplary embodiment in a super-heterodyne architecture, the filter 242, PA 244, LNA 252 and filter 254 may be implemented separately from other components in the transmitter 230 and receiver 250 (e.g., such a configuration may implement a millimeter wave integrated circuit (mmW-IC) or other super-heterodyne based architecture).

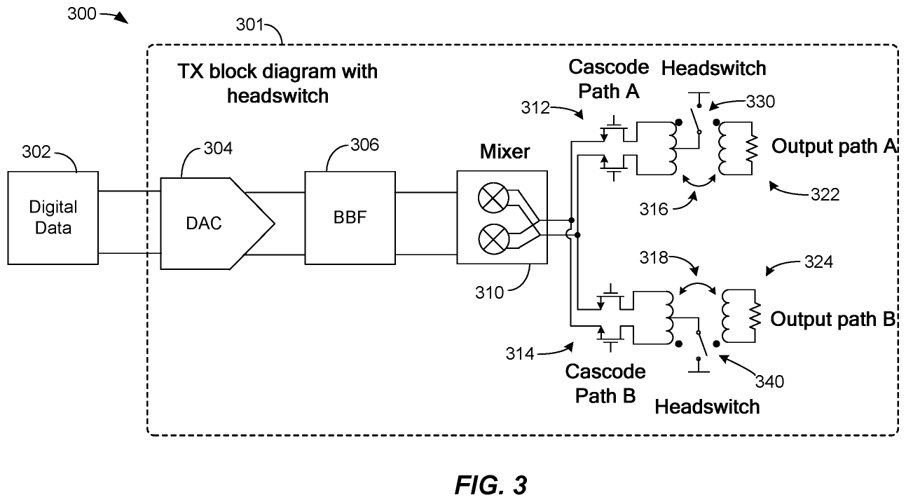

FIG. 3 is a block diagram showing a circuit 300 illustrating a portion of a transceiver of FIG. 2 that may be implemented in a wireless device or base station of FIG. 1. For example, the circuit 300 may comprise a portion 301 of the transceiver 220 FIG. 2).

In an exemplary embodiment, the circuit 300 may comprise a baseband element 302, a digital-to-analog converter (DAC) 304, a baseband filter (BBF) 306, a mixer 310, a cascode path 312 (cascode path A), a cascode path 314 (cascode path B), an electromagnetic (EM) element 316, an EM element 318, an output path 322 (output path A), and an output path 324 (output path B). In an exemplary embodiment, a head switch 330 may be selectively connected to the EM element 316 and a head switch 340 may be selectively connected to the EM element 318.

Although two cascode paths 312 and 314 are shown for illustration, the circuit 300 may include more or fewer cascode paths, depending on implementation.

In some exemplary embodiments, the cascode path 312 and the cascode path 314 may be part of the mixer 310.

As used herein, the term “selectively connected” is used to describe various ways that the head switch 330 can provide selected voltages to the EM element 316 and to transistors in the cascode path 312, and various ways that the head switch 340 can provide selected voltages to the EM element 318 and to transistors in the cascode path 314.

In an exemplary embodiment, the baseband element 302 may be configured to provide digital baseband information signals, generally referred to as digital data, to the DAC 304. The DAC 304 may convert the digital signal(s) from the baseband element 302 to analog signals that may be provided to the BBF 306. The BBF 306 may provide filtered analog information signals to the mixer 310.

In an exemplary embodiment, the mixer 310 may be configured to operate on single-ended signals or differential signals. In an exemplary embodiment, the mixer 310 may be an in-phase/quadrature (I/Q) mixer configured to generate I and Q signals for transmission. In some embodiments, the mixer 310 will perform signal frequency translation between baseband and RF frequencies, as shown in FIG. 3. In other embodiments, the mixer 310 will perform signal frequency translation between baseband and intermediate frequency (IF) and another mixer will perform signal frequency translation between IF and RF frequencies. In an exemplary embodiment, the I output and Q output of the mixer 310 may be provided to the cascode path 312 and to the cascode path 314.

In an exemplary embodiment, the cascode path 312 is connected to the EM element 322 and the cascode path 314 is connected to the EM element 318. The EM element 316 and the EM element 318 may be transformers, baluns or other EM elements. The EM element 316 provides an output signal to the output path 322 and the EM element 318 provides an output signal to the output path 324. The output path 322 and the output path 324 may be connected to one or more amplifiers, switches, diplexers, duplexers, and antennas or antenna elements.

In some exemplary embodiments, it may be particularly useful to implement the circuit 300 in a base station (such as a base station 130 or 132 of FIG. 1).

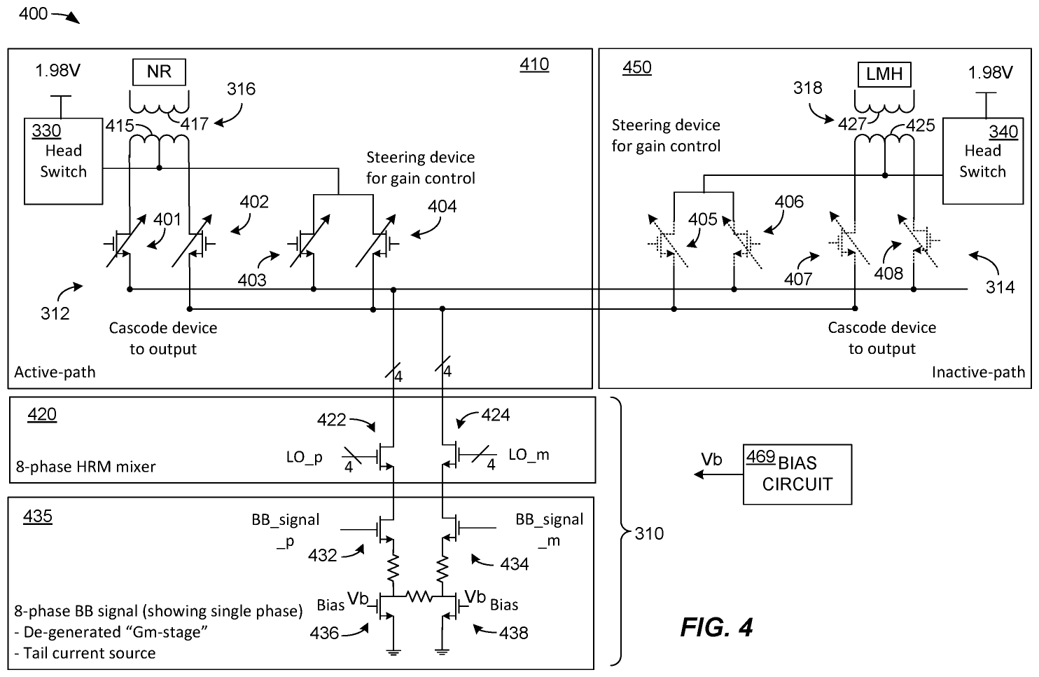

FIG. 4 is a diagram showing a circuit 400 illustrating a detailed view of a portion of the circuit of FIG. 3. In an exemplary embodiment, the circuit 400 comprises a portion of the transmit architecture of the circuit 300 of FIG. 3. In an exemplary embodiment, the circuit 400 comprises portions of the mixer 310, cascode paths 312 and 314, EM elements 316 and 318, and head switches 330 and 340 of FIG. 3. In an exemplary embodiment, the circuit 400 comprises an active path 410, an inactive path 450, a mixer 420 (e.g., a harmonic rejection mixer (HRM); however, other mixer architectures are possible), and a degenerated gain stage 435.

In an exemplary embodiment, the mixer 420 and the degenerated gain stage 435 are connected to the cascode path 312 (cascode path A) and to the cascode path 314 (cascode path B). In an exemplary embodiment, the mixer 420 may comprise mixer transistors 422 and 424. However, although only two mixer transistors 422 and 424 are shown, the mixer 420 typically comprises many additional transistors. In an exemplary embodiment, the mixer transistors 422 and 424 receive local oscillator (LO) signals LO_p and LO_m, respectively, at their gates, typically from the TX LO signal generator 290 of FIG. 2 in this example.

In an exemplary embodiment, the degenerated gain stage 435 may comprise gain (Gm) transistors 432 and 434 and degeneration transistors 436 and 438. In an exemplary embodiment, the degeneration transistors 436 and 438 may also be referred to as tail current sources. In an exemplary embodiment, baseband information signals BB_signal_p and BB_signal_m (from the baseband filter 306 of FIG. 3 for example), may be provided to the gates of the transistors 432 and 434, respectively. The transistors 436 and 438 may receive bias signals, Vb, at their gates from, for example, a bias circuit 469 that may be an external circuit and that may be controlled by a control signal from the data processor 210 (FIG. 2) or another controller.

In an exemplary embodiment, the active path 410 comprises the head switch 330 (FIG. 3), the EM element 316 (FIG. 3) and the cascode path 312 (FIG. 3). The EM element 316 may comprise a first winding 415 and a second winding 417. In an exemplary embodiment, a center tap of the first winding 415 may be connected to the head switch 330. The first winding 415 may also be connected to the drains of the transistors 401 and 402, thus connecting the drains of the transistor 401 and the transistor 402 to the head switch 330 via the first winding 415. The drains of the transistors 403 and 404 are connected directly to the head switch 330. The second winding 417 may provide an output, in this example an output related to a new radio (NR) communication signal. The cascode path 312 may comprise transistors 401, 402, 403 and 404. The transistors 401 and 402 are cascode transistors and the transistors 403 and 404 may comprise a current steering function to provide output gain control. Although described as being part of the cascode path 312, the transistors 403 and 404 are not cascode transistors and the cascode path 312 may or may not include current steering devices for gain control. For example, the determination of which of the transistors 401, 402, 403 and 404 that are on is dependent on the desired amount of gain. In an exemplary embodiment, the transistors 401, 402, 403 and 404 are shown in solid bold line to indicate that in this example, they are part of the active path 410 and processing a communication signal. In an exemplary embodiment, the active path 410 may process a communication signal during a certain communication mode (e.g., for example the active path 410 may be used for 5G new radio (NR) signals).

In an exemplary embodiment, the inactive path 450 comprises the head switch 340 (FIG. 3), the EM element 318 (FIG. 3) and the cascode path 314 (FIG. 3). The EM element 318 may comprise a first winding 425 and a second winding 427. A center tap of the first winding 425 may be connected to the head switch 340. The first winding 425 may also be connected to the drains of the transistors 407 and 408 thus connecting the drains of the transistor 407 and the transistor 408 to the head switch 340 via the first winding 425. The drains of the transistors 405 and 406 are connected directly to the head switch 340. The second winding 427 may provide an output, in this example an output related to a low band, mid band, high band (LMH) communication signal.

The cascode path 314 may comprise transistors 405, 406, 407 and 408. The transistors 407 and 408 are cascode transistors and the transistors 405 and 406 may comprise a current steering function to provide output gain control. For example, the determination of which of the transistors 405, 406, 407 and 408 that are on is dependent on the desired amount of gain. Although described as being part of the cascode path 314, the transistors 405 and 406 are not cascode transistors and the cascode path 314 may or may not include current steering devices for gain control. In an exemplary embodiment, the transistors 405, 406, 407 and 408 are shown in dotted line to indicate that in this example, they are part of the inactive path 450 and not actively processing a communication signal. However, even if the transistors 405, 406, 407 and 408 are not actively processing a communication signal, it is desirable to provide a selective control and bias to the transistors 405, 406, 407 and 408 in the inactive path 314. In an exemplary embodiment, the inactive path 450 may be inactive during a certain communication mode (e.g., for 5G NR signals) but be active during other modes (e.g., active for certain LTE LB, HB, MB (low band, mid band, high band (LMH)) modes).

Although described as applicable to stacked transistors in a mixer architecture, the head switch for a stacked transistor structure described herein is applicable to other stacked transistor structures, such as, for example, stacked transistor structures in a power amplifier (PA) a driver amplifier (DA) or other stacked transistor structures.

Further, while two cascode paths are shown in FIG. 4 and in other figures below, three or more cascode paths may be implemented. For example, a third cascode path would have a third EM element and devices.

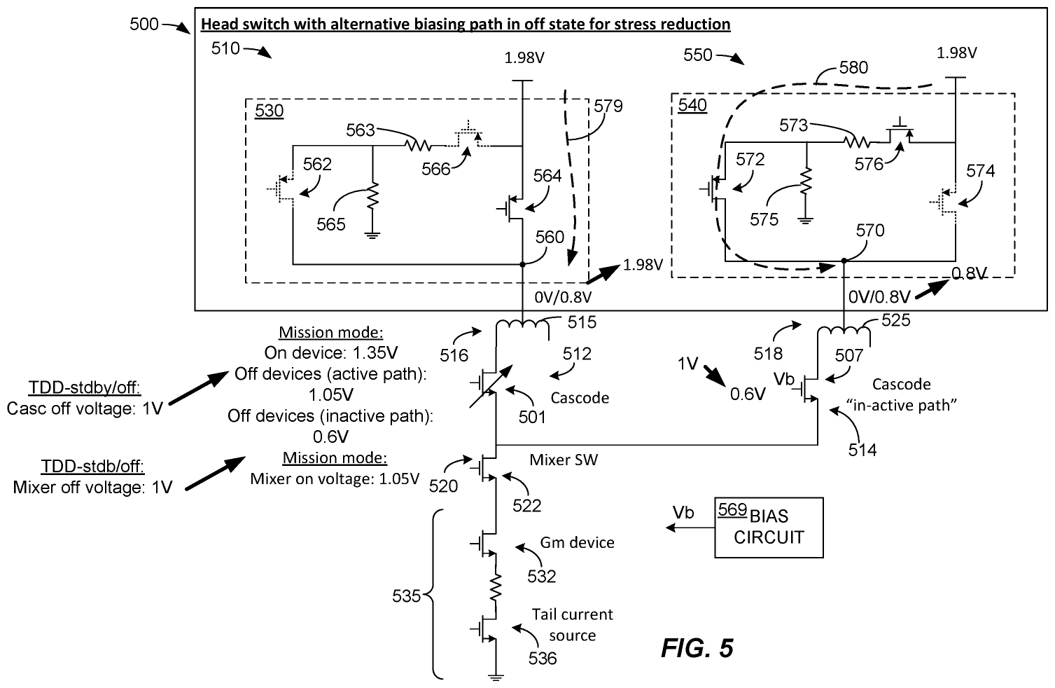

FIG. 5 is a diagram showing a circuit 500 illustrating an exemplary embodiment of the head switches of FIG. 3 and FIG. 4. Elements in FIG. 5 that are similar to elements in FIG. 4 will be referred to using the nomenclature 5XX, where an element in FIG. 5 labeled 5XX is similar to an element in FIG. 4 labeled 4XX.

The circuit 500 comprises an active path 510 and an inactive path 550. The head switch 530 is illustrated as being in the active path 510 and the head switch 540 is illustrated as being in the inactive path 550.

In an exemplary embodiment, the head switch 530 may comprise transistors 562, 564 and 566, and may comprise resistances 563 and 565. The resistances 563 and 565 may form a resistive divider. In an exemplary embodiment where the head switch 530 is in the active path 510, the transistor 564 is conductive (shown in solid line) and the transistors 562 and 566 are non-conductive (shown in dotted line). In an exemplary embodiment, the transistor 564 may form a first (or primary) bias path 579. In the example shown in FIG. 5 where the transistor 564 is conductive, a node 560 may have a voltage that is substantially equal to the supply voltage, which is shown as 1.98V in this example provided by the first bias path 579 as a non-limiting example. In some embodiments, the supply voltage may alternatively be referred to as a system voltage.

In an exemplary embodiment, the head switch 540 may comprise transistors 572, 574 and 576, and may comprise resistances 573 and 575. The resistances 573 and 575 may form a resistive divider. In an exemplary embodiment where the head switch 540 is in the inactive path 550, the transistor 572 is conductive (shown in solid line) and the transistor 576 is conductive (shown in solid line), and the transistor 574 is non-conductive (shown in dotted line). In an exemplary embodiment, the transistors 572 and 576 and the resistances 573 and 575 form an auxiliary bias path 580 when the transistors 576 and 572 are conductive and the transistor 574 is non-conductive. In this manner, the supply voltage at node 570 may be reduced to a lower value than the voltage that appears at the node 560 to bias the drains of the transistors in the cascode path 514 in the inactive path 550.

In some embodiments, a single head switch (e.g., head switch 530 or head switch 540) may be configured to provide a primary path 579 configured to provide a first supply voltage (e.g., head switch 530 in FIG. 5) and an auxiliary path 580 configured to provide a reduced supply voltage (e.g., head switch 540). Although shown as using a resistive divider to generate to lower supply voltage at node 570 in this example, the reduced supply voltage may also be generated using an external voltage supply of 0.8V in this example.

In an exemplary embodiment, the head switch 530 is connected to the EM element 516 at the node 560. The EM element 516 is connected to the cascode transistors in the cascode path 512. Although a single cascode transistor 501 is shown in the cascode path 512 for ease of illustration, the cascode transistor 501 is intended to represent all cascode transistors in the cascode path 312 of FIG. 3 and FIG. 4. For example, one or more additional cascode transistors would be connected to the other side of the first winding 515. The cascode transistor 501 is connected to the mixer 520. The mixer 520 is connected to the degenerated gain stage 535. Although a single mixer transistor 522 is shown in FIG. 5 in the mixer 520 and single transistors are shown as the Gm device 532 and the tail current source 536 in the degenerated gain stage 535, the mixer 520 and the degenerated gain stage 535 may include additional transistors as described above and shown in FIG. 4. In an exemplary embodiment, the mixer 520 (mixer transistor 522) receives a local oscillator (LO) signal, the Gm device 532 receives a baseband information signal and the tail current source 536 receives a bias signal, Vb, as described above in FIG. 4.

In an exemplary embodiment, the head switch 540 is connected to the EM element 518 at the node 570. The EM element 518 is connected to the cascode path 514. Although a single transistor 507 is shown in FIG. 5 in the cascode path 514, the cascode path 514 may include additional transistors as described above.

Although only the first winding 515 is shown in the EM element 516 and only the first winding 525 is shown in the EM element 518 for ease of illustration, the EM element 516 and the EM element 518 would each include a second winding, such as the second winding 417 and the second winding 427 in FIG. 4 to provide circuit output paths as described above in FIG. 3 and FIG. 4.

In the inactive path 550, it is desirable to prevent a random voltage at node 570 when the head switch 540 is configured as shown in FIG. 5. In an exemplary embodiment, the transistors 572 and 573 and the resistances 573 and 575 form what is referred to as an auxiliary bias path 580 for the cascode transistors in the cascode path 514. In this manner, a random voltage is prevented from appearing at the node 570. In an exemplary embodiment, a voltage of approximately 0.8V (as one example) appears at the node 570 as a result of the voltage division performed by the resistances 573 and 575 and is applied to the drains of the cascode transistors in the cascode path 514. In other embodiments, an external voltage source may be used to provide the reduced supply voltage at node 570. In an exemplary embodiment, the gates of the transistors in the cascode path 514 also receive a bias signal at their gates of, for example, a bias voltage of 0.6V from a bias circuit 569 that may be an external circuit and that may be controlled by a control signal from the data processor 210 (FIG. 2) or another controller.

In an exemplary embodiment, the voltage at the node 560 transitions from approximately 0V-0.8V when the head switch 530 is in a stand-by or off condition, to an exemplary voltage of 1.98V when the head switch 530 is in a mission mode condition.

In an exemplary embodiment, the voltage at the node 570 transitions from approximately 0V-0.8V when the head switch 540 is in a stand-by or off condition, to a voltage of approximately 0.8V when the head switch 540 is in a mission mode condition.

In an exemplary embodiment, a voltage at the gates of cascode transistors in the cascode path 512 (in the active path 510) are at an example voltage of 1V in a stand-by or off condition, and transition to a voltage of approximately 1.35V when in an on condition in mission mode.

In an exemplary embodiment, a voltage at the gates of cascode transistors in the cascode path 514 (in the inactive path 550) are at an example voltage of 1V in a stand-by or off condition, and transition to a voltage of approximately 0.6V when in an on condition in mission mode.

In mission mode, the voltage at the gates of any ON cascode transistors in the cascode path 512 (in the active path 510) is approximately 1.35V; the voltage at the gates of any OFF cascode transistors in the cascode path 512 (in the active path 510) is approximately 1.05V; and the voltage at the gates of any OFF cascode transistors in the cascode path 514 (in the inactive path 550) is approximately 0.6V.

In an exemplary embodiment, the voltage at the gates of any transistors in the mixer 520 is approximately 1V in stand-by mode and transitions to approximately 1.05V in mission mode.

In an exemplary embodiment, placing the voltage of approximately 0.8V at the node 570 (the drain of the transistors in the cascode path 514) and placing a gate voltage of approximately 0.6V at the gates of the transistors in the cascode path 514 ensures that the transistors in the cascode path 514 are off, thereby preventing a desired signal to be siphoned off from the active path cascode 512 as well as preventing the likelihood of an over-voltage condition being transferred to the transistors in the cascode path 514. Applying approximately 0.6V to the gate of the transistors in the cascode path 514 while the drain of the transistors in the cascode path 514 is at approximately 0.8V places the source of the transistors in the cascode path 514 at approximately 1.1V so that the transistors in the cascode path 514 are not overstressed.

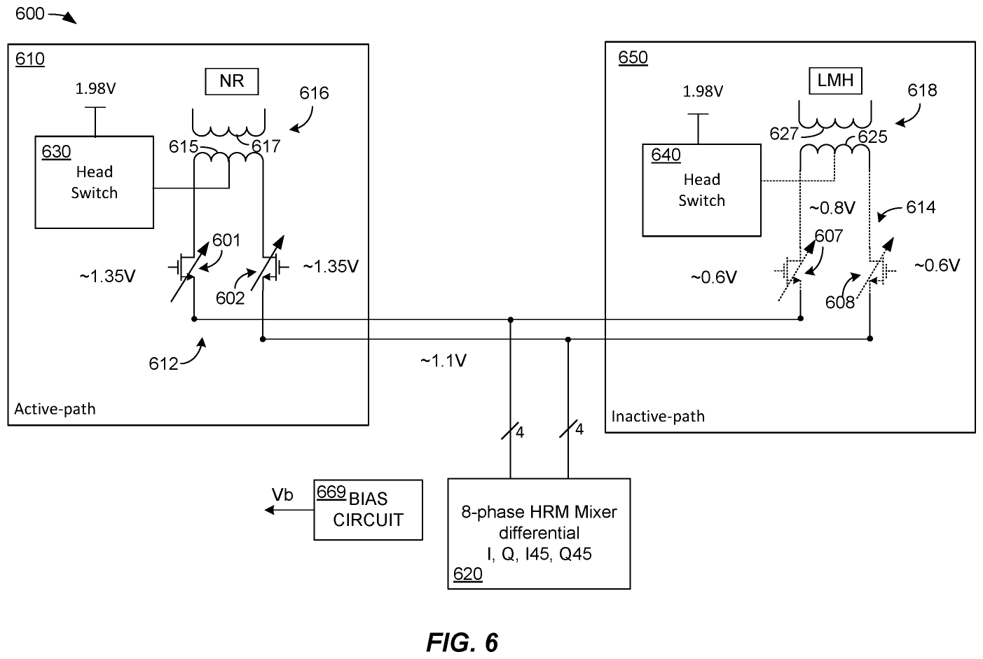

FIG. 6 is a diagram showing a circuit 600 illustrating an exemplary embodiment of the desired voltages associated with the head switches of FIG. 5. Elements in FIG. 6 that are similar to elements in FIG. 4 and FIG. 5 will be referred to using the nomenclature 6XX, where an element in FIG. 6 labeled 6XX is similar to an element in FIG. 4 labeled 4XX or an element in FIG. 5 labeled 5XX.

In an exemplary embodiment, the circuit 600 comprises an active path 610 having a head switch 630. The head switch 630 is connected to an EM element 616 having a first winding 615 and a second winding 617. In an exemplary embodiment, a center tap of the first winding 615 may be connected to the head switch 630. The first winding 615 may also be connected to the drains of the transistors 601 and 602, thereby connecting the drains of the transistors 601 and 602 to the head switch 630 through the first winding 615. The second winding 617 may provide an output, in this example an output related to a new radio (NR) communication signal. Although two cascode transistors 601 and 602 are shown in the cascode path 612 of FIG. 6 for case of illustration, the cascode path 612 may include many more transistors. The current steering transistors (e.g., 403/404 of FIG. 4) are omitted from FIG. 6 for case of illustration.

In an exemplary embodiment, the circuit 600 comprises an inactive path 650 having a head switch 640. The head switch 640 is connected to an EM element 618 having a first winding 625 and a second winding 627. In an exemplary embodiment, a center tap of the first winding 625 may be connected to the head switch 640. The first winding 625 may also be connected to the drains of the transistors 607 and 608, thereby connecting the drains of the transistors 607 and 608 to the head switch 640 through the first winding 625. The second winding 627 may provide an output, in this example an output related to a low band, mid band, high band (LMH) communication signal. Although two cascode transistors 607 and 608 are shown in the cascode path 614 in FIG. 6 for case of illustration, the cascode path 614 may include many more transistors. The current steering transistors (e.g., 405/406 of FIG. 4) are omitted from FIG. 6 for case of illustration. In an exemplary embodiment, the current steering devices (not shown) in the inactive path 650 will receive the reduced supply voltage (0.8V) from the auxiliary path of the inactive path head switch 640 in this example.

A mixer 620 may be connected to the sources of the transistors 601, 602, 607 and 608. While labeled as a particular HRM mixer, other mixer topologies may be possible for the mixer 620. In an exemplary embodiment, the mixer 620 is similar to the mixer 520 of FIG. 5, and the gain transistor 532 and tail current source 536 in the degenerated gain stage 535 of FIG. 5 are omitted from FIG. 6 for case of illustration.

In an exemplary embodiment, the head switch 640 applies an approximate 0.8V bias voltage to the drains of the cascode transistor 607 and 608 in the inactive path 650. An external bias circuit 669 may apply an approximate 0.6V bias to the gates of the cascode transistors 607 and 608 to ensure that the cascode transistors 607 and 608 are off. The bias signal that is applied to the gates of the transistors 607 and 608 may be provided by the bias circuit 669 that may be an external circuit and that may be controlled by the data processor 210 (FIG. 2) or another controller.

In an exemplary embodiment, it is not desirable to have the drain of the cascode transistors 607 and 608 at a floating voltage of, for example, 0V-0.8V due to stresses that may be presented to the transistors (for example, the transistors in the cascode path 614) during off to on transient conditions.

In an exemplary embodiment, a voltage of approximately 1.1V appears at the sources of the cascode transistors 601, 602, 607 and 608, and is therefore applied to the transistors (not shown in FIG. 6) in the mixer 620.

In an exemplary embodiment, the head switch 630 applies a supply voltage (approximately 1.98V in this example) to the drains of the transistors 601 and 602. An external bias circuit 669 applies an approximate 1.35V bias voltage to the gates of the transistors 601 and 602.

In an exemplary embodiment, the head switch 640 applies a reduced supply voltage (approximately 0.8V in this example) to the drains of the transistors 607 and 608. In an exemplary embodiment, an external bias circuit 669 may apply an approximate 0.6V bias voltage to the gates of the transistors 607 and 608 to ensure that the transistors 607 and 608 remain non-conductive.

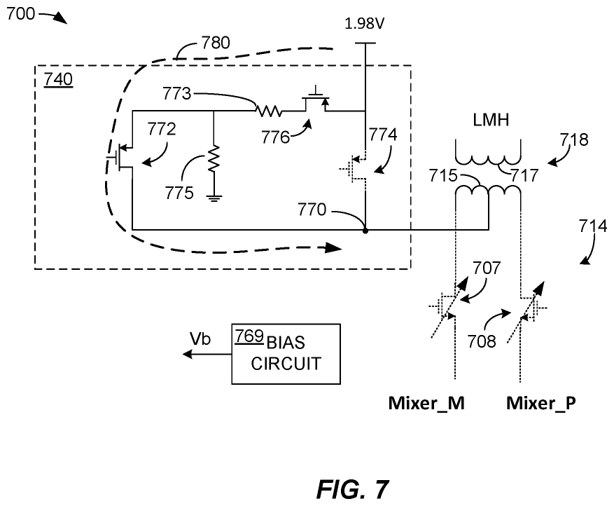

FIG. 7 is a diagram showing a circuit 700 illustrating an exemplary embodiment of an inactive path head switch of FIG. 6. Elements in FIG. 7 that are similar to elements in FIG. 4, FIG. 5 and FIG. 6 will be referred to using the nomenclature 7XX, where an element in FIG. 7 labeled 7XX is similar to an element in FIG. 4 labeled 4XX, an element in FIG. 5 labeled 5XX or an element in FIG. 6 labeled 6XX.

In an exemplary embodiment, the circuit 700 shows a head switch 740 having an auxiliary bias path 780 having transistors 776 and 772 and resistances 773 and 775 configured to provide an approximate 0.8V voltage to the node 770. An approximate voltage of 0.8V at the node 770 can bias the drains of the cascode transistors 707 and 708 in the cascode path 714 when the cascode transistors 7078 and 708 are in the off position. A gate voltage of approximately 0.6V provided to the cascode transistors 707 and 708 ensures that the transistors 707 and 708 remain off. In an exemplary embodiment, the gate voltage is provided by an external bias circuit 769 that may be controlled by the data processor 2010 (FIG. 2) or another controller.

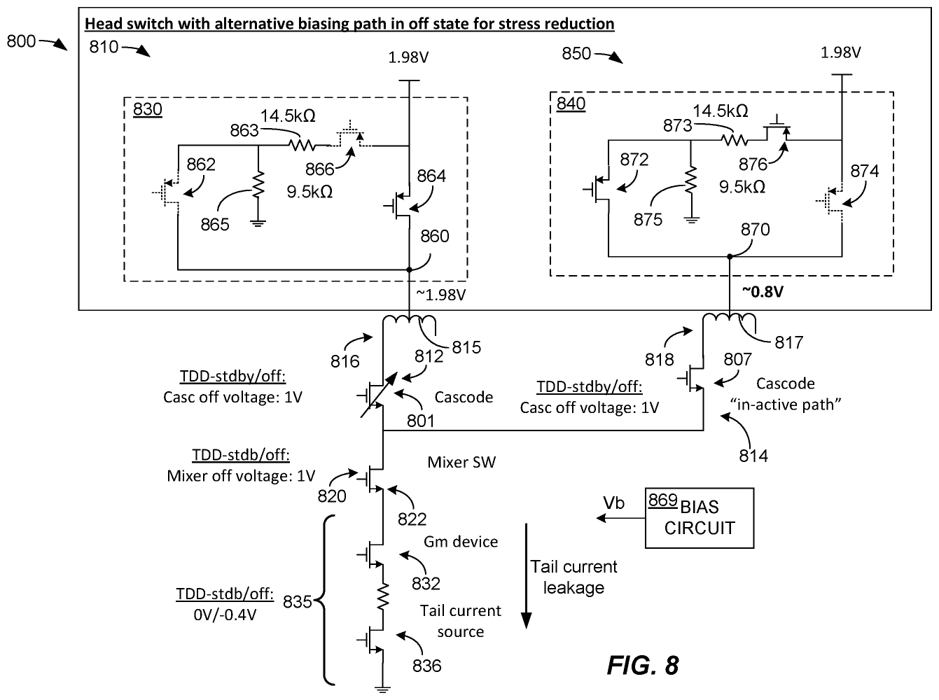

FIG. 8 is a is a diagram showing a circuit 800 illustrating a detailed view of a portion of the circuit of FIG. 3 and an exemplary embodiment of the circuit 500 of FIG. 5. Elements in FIG. 8 that are similar to elements in FIG. 3 and FIG. 5 will be referred to using the nomenclature 8XX, where an element in FIG. 8 labeled 8XX is similar to an element in FIG. 3 labeled 3XX or an element in FIG. 5 labeled 5XX.

In an exemplary embodiment, the circuit 800 illustrates some of the voltages provided by the head switch 830 and the head switch 840. In an exemplary embodiment, from a stand-by (or off) state the head switch 830 in the active path 810 is activated first, that is, before the head switch 840 in the inactive path 850 is activated. Activating the head switch 830 in the active path 810 first ensures that all of the tail current flowing through the cascode path 812, cascode path 814, mixer 820 and the transistors 832 and 836 in the degenerated gain stage 835 passes through only the cascode path 812 associated with the head switch 830 in the active path 810. Because there is no tail current flowing through the head switch 840 in the inactive path 850, the resistive divider (resistances 873 and 875) accurately provides the desired 0.8V to the center tap of the EM element 818 and to the drains of the transistors (e.g., transistor 807) in the cascode path 814 in this manner, all off-to-on transitions can be accurately accomplished and are robust against voltage anomalies that may stress the transistors in the cascode paths 812 and 814, the transistors in the mixer 820 and the transistors in the degenerated gain stage 835.

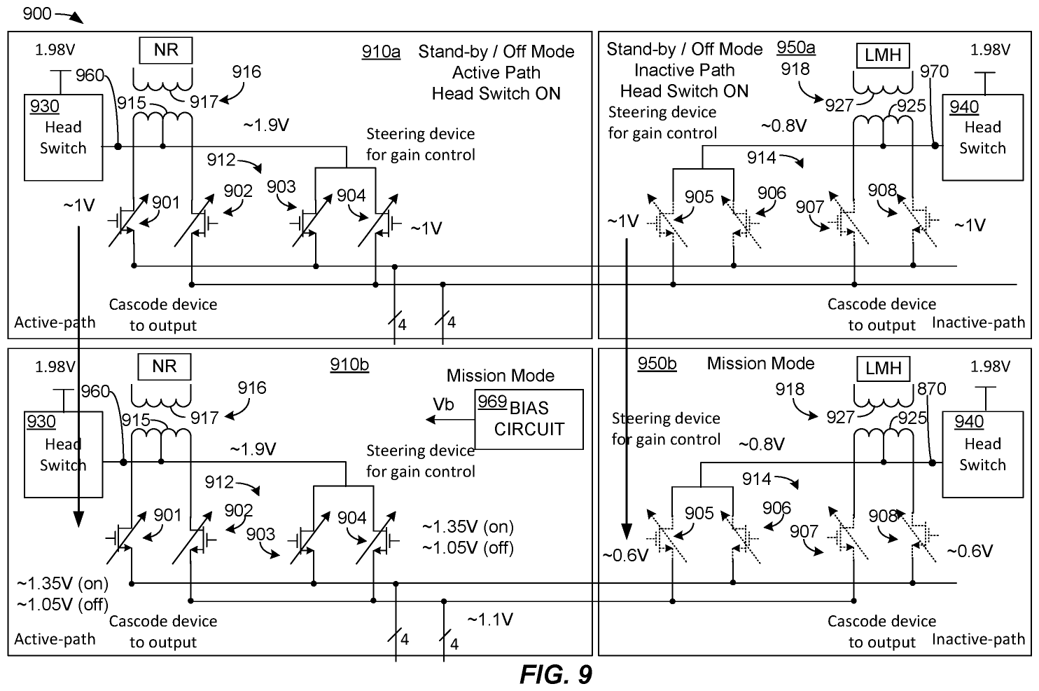

FIG. 9 is a diagram showing a circuit 900 in accordance with an exemplary embodiment of the disclosure. Elements in FIG. 9 that are similar to elements in FIG. 3, FIG. 4 and FIG. 5 will be referred to using the nomenclature 9XX, where an element in FIG. 9 labeled 9XX is similar to an element in FIG. 3 labeled 3XX, an element in FIG. 4 labeled 4XX or an element in FIG. 5 labeled 5XX.

In an exemplary embodiment, the circuit 900 illustrates gate voltage transitions when switching from an OFF mode to a mission mode. For example, the active path 910a shows active path voltages in an OFF mode and the active path 910b shows active path voltages in mission mode. Similarly, the inactive path 950a shows inactive path voltages in an OFF mode and the inactive path 950b shows inactive path voltages in mission mode.

In an exemplary embodiment, in the active path 910a in stand-by mode, a supply voltage of approximately 1.9V (exemplary 1.98V supply voltage) is provided by the head switch 930 to the node 960. This supply voltage is provided to a center tap of the first winding 915 of the EM element 916 and thus indirectly to the drains of the cascode transistors 901, 902. The head switch output is directly provided to the drains of the transistors 903 and 904 in the cascode path 912. A gate voltage of approximately 1V is provided to the gates of the transistors 901, 902, 903 and 904 in the cascode path 912 by an external bias circuit 969 controlled by the data processor 210 (FIG. 2) or another controller. The external bias circuit 969 is shown as being in the active path 910b for convenience of illustration only. The external bias circuit 969 may provide bias signals to any of the transistors in the active path 910a, the active path 910b, the inactive path 950a, and the inactive path 950b.

In an exemplary embodiment, in the active path 910b in mission mode, a supply voltage of approximately 1.9V (exemplary 1.98V supply voltage) is provided by the head switch 930 to the node 960. This supply voltage is provided to a center tap of the first winding 915 of the EM element 916 and thus indirectly to the drains of the cascode transistors 901, 902; and directly to the drains of the transistors 903 and 904 in the cascode path 912. A gate voltage of approximately 1.35V is provided to the gates of the transistors 901, 902, 903 and 904 in the cascode path 912 that are on; and a gate voltage of approximately 1.05V is provided to the gates of the transistors 901, 902, 903 and 904 in the cascode path 912 that are off. The determination of which of the transistors 901, 902, 903 and 904 that are on is dependent on the desired amount of gain. The gate voltages provided to the transistors 901, 902, 903 and 904 may be provided by the external bias circuit 969 controlled by the data processor 210 (FIG. 2) or another controller.

In an exemplary embodiment, in the inactive path 930a in stand-by mode, a supply voltage of approximately 0.8V is provided by the head switch 940 to the node 970. This supply voltage is provided to a center tap of the first winding 925 of the EM element 918 and indirectly to the drains of the cascode transistors 907 and 908 and directly to the drains of the transistors 905 and 906 in the cascode path 914. A gate voltage of approximately 1V is provided to the gates of the transistors 905, 906, 907 and 908 in the cascode path 914 by the external bias circuit 969 controlled by the data processor 210 (FIG. 2) or another controller.

In an exemplary embodiment, in the inactive path 930b in mission mode, a supply voltage of approximately 0.8V is provided by the head switch 940 to the node 970. This supply voltage is provided to a center tap of the first winding 925 of the EM element 918 and indirectly to the drains of the cascode transistors 907 and 908, and directly to the drains of the transistors 905 and 906 in the cascode path 914. A gate voltage of approximately 0.6V is provided to the gates of the transistors 905, 906, 907 and 908 in the cascode path 914. The gate voltages provided to the transistors 905, 906, 907 and 908 may be provided by the external bias circuit 969 controlled by the data processor 210 (FIG. 2) or another controller. This results in a voltage of approximately 1.1V appearing at the sources of the transistors 901, 902, 903, 904, 905, 906, 907 and 908 as input to the mixer (not shown in FIG. 9). In this manner, the transistors 905, 906, 907 and 908 in the cascode path 914 are protected from over-voltage conditions and other voltage transients during transition from stand-by mode to mission mode.

In an exemplary embodiment, a head switch (such as the head switch 930 or the head switch 940, or any head switch described herein) having a “mission mode” and an “auxiliary” path can also be implemented in embodiments with only a single signal path (e.g., only an NR signal path) where the head switch structure can be used to provide the auxiliary voltage of 0.8V during power up and then to provide the mission mode voltages as the gates of the transistors are biased up from the 0.8V to the full 1.9V, for example.

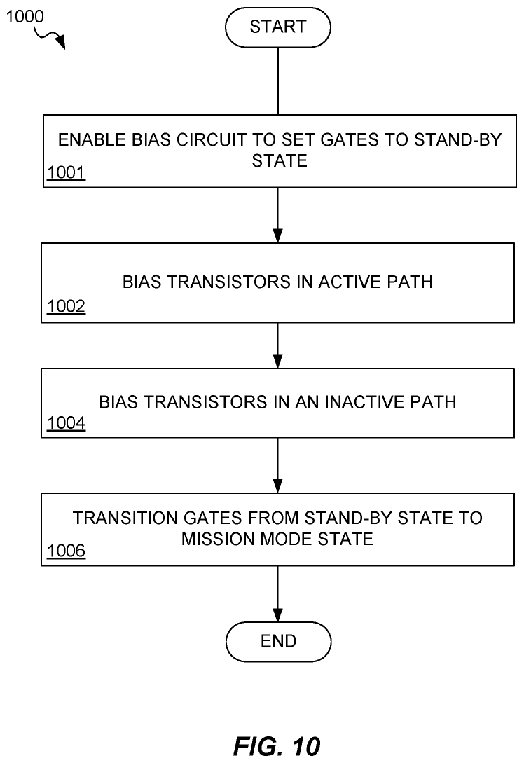

FIG. 10 is a flow chart 1000 describing an example of the operation of a method for biasing a stacked transistor structure. The blocks in the method 1000 can be performed in or out of the order shown, and in some embodiments, can be performed at least in part in parallel.

In block 1001, the gates of the transistors in the cascode path 912 are biased from a fully off/powered down state during initial power up where all gates are ˜0V to the stand-by state/off state.

In block 1002, transistors in the active path are biased. For example, the head switch 930 in the active path 910 may be activated before the head switch 940 in the inactive path 950 to bias the drains of the transistors 901, 902, 902 and 904 in the cascode path 912. An external bias circuit 969 may be configured to bias the gates of the transistors 901, 902, 903 and 904 in the cascode path 912.

In block 1004, transistors in the inactive path are biased. For example, the head switch 940 in the inactive path 910 may be activated to bias the drains of the transistors 905, 906, 907 and 908 in the cascode path 914. An external bias circuit 969 may be configured to bias the gates of the transistors 905, 906, 907 and 908 in the cascode path 914.

In block 1006, the gates of the transistors may be transitioned from a stand-by state to a mission mode state. For example, the gates of the transistors 901, 902, 903, and 904 in the cascode path 912 in the active path 910 are transitioned from stand-by mode to mission mode and the transistors 905, 906, 907, and 908 in the cascode path 914 in the active path 910 are transitioned from stand-by mode to mission mode. For example, the transistors 901, 902, 903 and 904 may have their gate voltages transitioned from approximately 1V to approximately 1.35V (if on) or 1.05V (if off). For example, the transistors 905, 906, 907 and 908 may have their gate voltages transitioned from approximately 1V to approximately 0.6V.

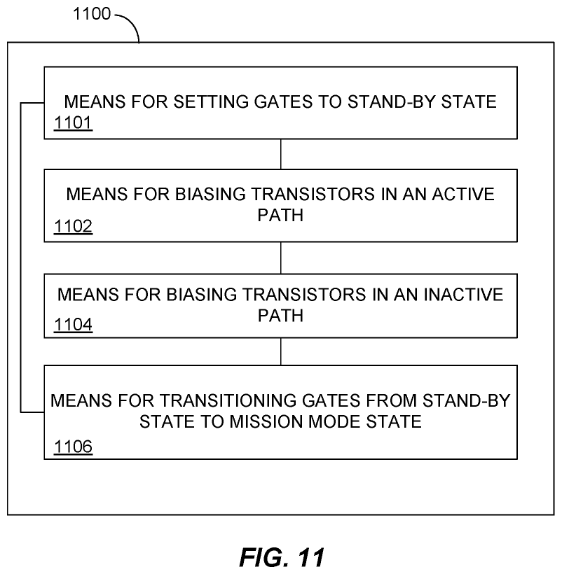

FIG. 11 is a functional block diagram of an apparatus 1100 for biasing a stacked transistor structure. The apparatus 1100 comprises means 1101 for biasing the gates of the transistors in the cascode path. In certain embodiments, the means 1101 for biasing the gates of the transistors in the cascode path can be configured to perform one or more of the functions described in operation block 1001 of method 1000 (FIG. 10). In an exemplary embodiment, the means 1101 for biasing the gates of the transistors in the cascode path may comprise the bias circuit 969 biasing the gates of the transistors in the cascode path 912 from a fully off/powered down state during initial power up where all gates are ˜0V to the stand-by state/off state.

The apparatus 1100 comprises means 1102 for biasing transistors in the active path. In certain embodiments, the means 1102 for biasing transistors in the active path can be configured to perform one or more of the functions described in operation block 1002 of method 1000 (FIG. 10). In an exemplary embodiment, the means 1102 for biasing transistors in the active path may comprise activating the head switch 930 in the active path 910 before the head switch 940 in the inactive path 950 to bias the drains of the transistors 901, 902, 902 and 904 in the cascode path; and configuring the external bias circuit 969 to bias the gates of the transistors 901, 902, 903 and 904 in the cascode path 912.

The apparatus 1100 comprises means 1104 for biasing transistors in the inactive path. In certain embodiments, the means 1104 for biasing transistors in the inactive path can be configured to perform one or more of the functions described in operation block 1004 of method 1000 (FIG. 10). In an exemplary embodiment, the means 1104 for biasing transistors in the inactive path may comprise activating the head switch 940 in the inactive path 950 after the head switch 930 in the active path 910 to bias the drains of the transistors 905, 906, 907 and 908 in the cascode path 914; and configuring the external bias circuit 969 to bias the gates of the transistors 905, 906, 907 and 908 in the cascode path 914.

The apparatus 1100 comprises means 1106 for transitioning the gates of the transistors from a stand-by state to a mission mode state. In certain embodiments, the means 1106 for transitioning the gates of the transistors from a stand-by state to a mission mode state can be configured to perform one or more of the functions described in operation block 1006 of method 1000 (FIG. 10). In an exemplary embodiment, the means 1106 for transitioning the gates of the transistors from a stand-by state to a mission mode state may comprise transitioning the gate voltages of the transistors 901, 902, 903 and 904 may from approximately 1V to approximately 1.35V (if on) or 1.05V (if off); and transitioning the gate voltages of the transistors 905, 906, 907 and 908 from approximately 1V to approximately 0.6V.

Implementation examples are described in the following numbered clauses:

1. A head switch architecture for a stacked transistor structure, comprising: a first head switch located in an active path, the first head switch configured to provide a supply voltage to a first cascode path; and a second head switch located in an inactive path, the second head switch configured to provide a reduced supply voltage to a second cascode path.

2. The head switch architecture of clause 1, wherein the reduced supply voltage is provided by an auxiliary bias path comprising a pair of transistors and a resistive divider, the resistive divider configured to provide the reduced supply voltage to the second cascode path.

3. The head switch architecture of any of clauses 1 or 2, wherein the reduced supply voltage is provided to a drain of a cascode transistor in the second cascode path.

4. The head switch architecture of clause 3, further comprising an external bias circuit configured to provide a gate voltage to the gate of the cascode transistor in the second cascode path to turn the cascode transistor in the second cascode path off.

5. The head switch architecture of clause 4, further comprising when a cascode transistor in the first cascode path in the active path is transitioned from a stand-by state to a mission mode state, maintaining the cascode transistor in the second cascode path in an off state.

6. The head switch architecture of any of clauses 2 through 5, wherein the stacked transistor structure comprises at least a cascode transistor, a mixer transistor, a gain transistor and a tail current source transistor.

7. The head switch architecture of clause 6, wherein the supply voltage is configured to be applied to the first cascode path before the reduced supply voltage is applied to the second cascode path.

8. The head switch architecture of clause 7, wherein applying the supply voltage to the first cascode path before the reduced supply voltage is applied to the second cascode path is configured to ensure that a tail current flows only through the first cascode path, mixer transistor, gain transistor and tail current source transistor in the first cascode path.

9. A method for biasing a stacked transistor structure, comprising: applying a supply voltage to a first cascode path; applying a reduced supply voltage to a second cascode path; and applying a gate voltage to a gate of a cascode transistor in the first cascode path to transition the cascode transistor in the first cascode path from an off and/or a stand-by state to a mission mode state.

10. The method of clause 9, further comprising resistively dividing the supply voltage to obtain the reduced supply voltage.

11. The method of any of clauses 9 through 10, further comprising providing the reduced supply voltage to a drain of a cascode transistor in the second cascode path.

12. The method of any of clauses 9 through 11, wherein the first cascode path and the second cascode path each comprise a stacked transistor structure having at least a cascode transistor, a mixer transistor, a gain transistor and a tail current source transistor.

13. The method of clause 12, further comprising applying the supply voltage to the first cascode path before applying the reduced supply voltage to the second cascode path.

14. The method of clause 13, wherein applying the supply voltage to the first cascode path before the reduced supply voltage is applied to the second cascode path ensures that a tail current flows only through the first cascode path, mixer transistor, gain transistor and tail current source transistor in the first cascode path.

15. A device, comprising: means for applying a supply voltage to a first cascode path; means for applying a reduced supply voltage to a second cascode path; and means for applying a gate voltage to a gate of a cascode transistor in the first cascode path to transition the cascode transistor in the first cascode path from an off and/or a stand-by state to a mission mode state.

16. The device of clause 15, further comprising means for resistively dividing the supply voltage to obtain the reduced supply voltage.

17. The device of any of clauses 15 through 16, further comprising means for providing the reduced supply voltage to a drain of a cascode transistor in the second cascode path.

18. The device of any of clauses 15 through 17, wherein the first cascode path and the second cascode path each comprise a stacked transistor structure having at least a cascode transistor, a mixer transistor, a gain transistor and a tail current source transistor.

19. The device of any of clauses 15 through 18, further comprising means for applying the supply voltage to the first cascode path before applying the reduced supply voltage to the second cascode path.

20. The device of clause 19, wherein the means for applying the supply voltage to the first cascode path before the reduced supply voltage is applied to the second cascode path ensures that a tail current flows only through the first cascode path, mixer transistor, gain transistor and tail current source transistor in the first cascode path.

21. An apparatus comprising: a first head switch circuit coupled between a supply voltage and a first cascode transistor, the first cascode transistor coupled to a plurality of stacked transistors, the first head switch circuit comprising a first path coupled between the supply voltage and the first cascode transistor and configured to provide a first voltage to a first node that is between the first head switch circuit and a terminal of the first cascode transistor, the first head switch circuit further comprising a second path coupled between the supply voltage and the first cascode transistor and configured to provide a second voltage lower than the first voltage to the first node; and a second head switch circuit coupled between the supply voltage and a second cascode transistor, the second cascode transistor coupled to the plurality of stacked transistors, the second head switch circuit comprising a third path coupled between the supply voltage and the second cascode transistor and configured to provide a third voltage to a second node that is between the second head switch circuit and a terminal of the second cascode transistor, the first head switch circuit further comprising a fourth path coupled between the supply voltage and the second cascode transistor and configured to provide a fourth voltage lower than the third voltage to second node.

22. The apparatus of clause 21, wherein the first path comprises a transistor and the second path comprises a pair of transistors and a resistive divider.

23. The apparatus of clause 22, wherein the third path comprises a transistor and the fourth path comprises a pair of transistors and a resistive divider.

24. The apparatus of any of clauses 21 through 23, further comprising a mixer circuit comprising the plurality of stacked transistors.

25. The apparatus of any of clauses 21 through 24, wherein the plurality of stacked transistors comprises a mixer transistor, a gain transistor, and a tail current source transistor.

26. The apparatus of any of clauses 21 through 25, wherein when the first cascode transistor is transitioned from a stand-by state to a mission mode state, the second cascode transistor is maintained in an off state.

The circuit architecture described herein described herein may be implemented on one or more ICs, analog ICs, RFICs, mixed-signal ICs, ASICs, printed circuit boards (PCBs), electronic devices, etc. The circuit architecture described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

Although selected aspects have been illustrated and described in detail, it will be understood that various substitutions and alterations may be made therein without departing from the spirit and scope of the present invention, as defined by the following claims.

What is claimed is:

1. A head switch architecture for a stacked transistor structure, comprising:
a first head switch located in an active path, the first head switch configured to provide a supply voltage to a first cascode path; and
a second head switch located in an inactive path, the second head switch configured to provide a reduced supply voltage to a second cascode path.

2. The head switch architecture of claim 1, wherein the reduced supply voltage is provided by an auxiliary bias path comprising a pair of transistors and a resistive divider, the resistive divider configured to provide the reduced supply voltage to the second cascode path.

3. The head switch architecture of claim 1, wherein the reduced supply voltage is provided to a drain of a cascode transistor in the second cascode path.

4. The head switch architecture of claim 3, further comprising an external bias circuit configured to provide a gate voltage to the gate of the cascode transistor in the second cascode path to turn the cascode transistor in the second cascode path off.

5. The head switch architecture of claim 4, further comprising when a cascode transistor in the first cascode path in the active path is transitioned from a stand-by state to a mission mode state, maintaining the cascode transistor in the second cascode path in an off state.

6. The head switch architecture of claim 1, wherein the stacked transistor structure comprises at least a cascode transistor, a mixer transistor, a gain transistor and a tail current source transistor.

7. The head switch architecture of claim 6, wherein the supply voltage is configured to be applied to the first cascode path before the reduced supply voltage is applied to the second cascode path.

8. The head switch architecture of claim 7, wherein applying the supply voltage to the first cascode path before the reduced supply voltage is applied to the second cascode path is configured to ensure that a tail current flows only through the first cascode path, mixer transistor, gain transistor and tail current source transistor in the first cascode path.

9. A method for biasing a stacked transistor structure, comprising:
applying a supply voltage to a first cascode path;
applying a reduced supply voltage to a second cascode path; and
applying a gate voltage to a gate of a cascode transistor in the first cascode path to transition the cascode transistor in the first cascode path from an off and/or a stand-by state to a mission mode state.

10. The method of claim 9, further comprising resistively dividing the supply voltage to obtain the reduced supply voltage.

11. The method of claim 9, further comprising providing the reduced supply voltage to a drain of a cascode transistor in the second cascode path.

12. The method of claim 9, wherein the first cascode path and the second cascode path each comprise a stacked transistor structure having at least a cascode transistor, a mixer transistor, a gain transistor and a tail current source transistor.

13. The method of claim 12, further comprising applying the supply voltage to the first cascode path before applying the reduced supply voltage to the second cascode path.

14. The method of claim 13, wherein applying the supply voltage to the first cascode path before the reduced supply voltage is applied to the second cascode path ensure that a tail current flows only through the first cascode path, mixer transistor, gain transistor and tail current source transistor in the first cascode path.

15. A device, comprising:
means for applying a supply voltage to a first cascode path;
means for applying a reduced supply voltage to a second cascode path; and
means for applying a gate voltage to a gate of a cascode transistor in the first cascode path to transition the cascode transistor in the first cascode path from an off and/or a stand-by state to a mission mode state.

16. The device of claim 15, further comprising means for resistively dividing the supply voltage to obtain the reduced supply voltage.

17. The device of claim 15, further comprising means for providing the reduced supply voltage to a drain of a cascode transistor in the second cascode path.

18. The device of claim 15, wherein the first cascode path and the second cascode path each comprise a stacked transistor structure having at least a cascode transistor, a mixer transistor, a gain transistor and a tail current source transistor.

19. The device of claim 18, further comprising means for applying the supply voltage to the first cascode path before applying the reduced supply voltage to the second cascode path.

20. The device of claim 19, wherein the means for applying the supply voltage to the first cascode path before the reduced supply voltage is applied to the second cascode path ensures that a tail current flows only through the first cascode path, mixer transistor, gain transistor and tail current source transistor in the first cascode path.

21. An apparatus, comprising:
a first head switch circuit coupled between a supply voltage and a first cascode transistor, the first cascode transistor coupled to a plurality of stacked transistors, the first head switch circuit comprising a first path coupled between the supply voltage and the first cascode transistor and configured to provide a first voltage to a first node that is between the first head switch circuit and a terminal of the first cascode transistor, the first head switch circuit further comprising a second path coupled between the supply voltage and the first cascode transistor and configured to provide a second voltage lower than the first voltage to the first node; and
a second head switch circuit coupled between the supply voltage and a second cascode transistor, the second cascode transistor coupled to the plurality of stacked transistors, the second head switch circuit comprising a third path coupled between the supply voltage and the second cascode transistor and configured to provide a third voltage to a second node that is between the second head switch circuit and a terminal of the second cascode transistor, the first head switch circuit further comprising a fourth path coupled between the supply voltage and the second cascode transistor and configured to provide a fourth voltage lower than the third voltage to second node.

22. The apparatus of claim 21, wherein the first path comprises a transistor and the second path comprises a pair of transistors and a resistive divider.

23. The apparatus of claim 22, wherein the third path comprises a transistor and the fourth path comprises a pair of transistors and a resistive divider.

24. The apparatus of claim 21, further comprising a mixer circuit comprising the plurality of stacked transistors.

25. The apparatus of claim 21, wherein the plurality of stacked transistors comprises a mixer transistor, a gain transistor, and a tail current source transistor.

26. The apparatus of claim 21, wherein when the first cascode transistor is transitioned from a stand-by state to a mission mode state, the second cascode transistor is maintained in an off state.
